(19) United States
(12) Patent Application Publication
(10) Pub. No.: US 2015/0162439 A1
(43) Pub. Date: Jun. 11, 2015

(54) SEMICONDUCTOR DEVICE INCLUDING A TRANSISTOR HAVING A LOW DOPED DRIFT REGION AND METHOD FOR THE FORMATION THEREOF

(71) Applicant: Global Foundries Inc., Grand Cayman, KY (US)

(72) Inventors: Jan Hoentschel, Dresden (DE); Ran Yan, Dresden (DE); Stefan Flachowsky, Dresden (DE); Sven Beyer, Dresden (DE)

(73) Assignee: Global Foundries Inc., Grand Cayman, KY (US)

(21) Appl. No.: 14/099,375

(22) Filed: Dec. 6, 2013

(51) Int. Cl. H01L 29/78; H01L 29/06; H01L 29/66

(52) U.S. Cl. CPC H01L 29/7816; H01L 29/66431; H01L 29/66681; H01L 29/0649

(57) ABSTRACT

An illustrative semiconductor device disclosed herein includes a semiconductor substrate. The semiconductor substrate includes a first semiconductor material. In the first semiconductor material, a recess is provided. The recess is filled with a second semiconductor material having a different composition than the first semiconductor material. The semiconductor device further includes a first transistor including a source region, a drain region, a gate electrode and a channel region below the gate electrode. The channel region is arranged at two or more laterally opposite sides of the drain region. The source region is arranged at two or more laterally opposite sides of the channel region. The drain region includes a low doped drift region and a highly doped region. A dopant concentration in the low doped drift region is at least one of smaller than a dopant concentration in the highly doped region and approximately zero. At least the low doped drift region is provided in the second semiconductor material.

### BACKGROUND OF THE INVENTION

1. Field of the Invention

Generally, the present disclosure relates to the field of integrated circuits, in particular to integrated circuits including high voltage transistors.

2. Description of the Related Art

Integrated circuits include a large number of circuit elements, which include, in particular, field effect transistors. In a field effect transistor, a gate electrode is provided. The gate electrode can be separated from a channel region by a gate insulation layer providing electrical insulation between the gate electrode and the channel region. Adjacent the channel region, a source region and a drain region are provided.

The channel region, the source region and the drain region are formed in a semiconductor material, wherein the doping of the channel region is different from the doping of the source region and the drain region. Depending on an electric voltage applied to the gate electrode, the field effect transistor can be switched between an ON state and an OFF state, wherein an electrical conductivity of the channel region in the ON state is greater than an electrical conductivity of the channel region in the OFF state.

Applications of field effect transistors include the use of field effect transistors in digital circuits such as processors and memory devices. For improving the performance of digital circuits, it can be desirable to reduce the size of field effect transistors and adapt the field effect transistors for operation at a relatively low voltage of operation that is applied between the source region and the drain region of the field effect transistors.

Moreover, for reducing leakage currents and for increasing a gate capacitance of field effect transistors used in digital circuits, the high-k metal gate technique can be employed. According to the high-k metal gate technique, the gate insulation layer of field effect transistors is formed of a high-k material having a greater dielectric constant than silicon dioxide such as, for example, hafnium dioxide, zirconium dioxide, hafnium silicate and/or zirconium silicate. For adapting the work function of the gate electrode, a metal can be provided in the gate electrode, wherein different metals can be used for n-channel transistors and p-channel transistors.

Types of field effect transistors additionally include high voltage transistors, which are typically adapted for operation at substantially greater voltages of operation than field effect transistors used in digital circuits, and which can switch and/or control substantially greater currents than field effect transistors employed in digital circuits. High voltage transistors include laterally diffused metal oxide semiconductor (LDMOS) transistors which can be used, for example, in microwave and/or radio frequency amplifiers.

For some applications, it can be desirable to provide LDMOS transistors in a same integrated circuit as a digital circuit including, for example, a processor and/or a memory, wherein the processor can be adapted for operation at a relatively low voltage. The processor or an interface circuit connected between the processor and a high voltage circuit including one or more. LDMOS transistors can apply a gate voltage between a gate electrode and a source region of the LDMOS transistors for switching and/or controlling a high voltage that is greater than the voltage of operation of the processor.

In such applications, the implementation of LDMOS transistors is typically kept relatively simple, and an optimization of LDMOS transistors is only done by the geometric layout of the LDMOS transistors.

Since LDMOS transistors are configured for operation at a relatively high voltage of operation that is applied between the source region and the drain region of the LDMOS transistors, and relatively high electric currents can flow through the LDMOS transistors, a substantial amount of heat can be created in LDMOS transistors. According to conventional approaches, a relatively large area of LDMOS transistors can be required for ensuring a sufficient dissipation of heat from the LDMOS transistors. This can lead to an undesirable increase of the size of the integrated circuit. Further issues that can occur in the implementation of LDMOS transistors in a same integrated circuit as a digital circuit can include providing a sufficiently high breakthrough voltage of the LDMOS transistors.

The present disclosure provides semiconductor devices and methods that address the above-mentioned issues.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative semiconductor device disclosed herein includes a semiconductor substrate. The semiconductor substrate includes a first semiconductor material. In the first semiconductor material, a recess is provided. The recess is filled with a second semiconductor material having a different composition than the first semiconductor material. The semiconductor device further includes a first transistor including a source region, a drain region, a gate electrode and a channel region below the gate electrode. The channel region is arranged at two or more laterally opposite sides of the drain region. The source region is arranged at two or more laterally opposite sides of the channel region. The drain region includes a low doped drift region and a highly doped region. A dopant concentration in the low doped drift region is at least one of smaller than a dopant concentration in the highly doped region and approximately zero. At least the low doped drift region is provided in the second semiconductor material.

An illustrative method disclosed herein includes providing a semiconductor substrate including a first semiconductor material. A recess is formed in the first semiconductor material. The recess is filled with a second semiconductor material having a different composition than the first semiconductor material. A first transistor including a source region, a drain region, a gate electrode and a channel region below the gate electrode is formed. The channel region is arranged at two or more laterally opposite sides of the drain region, and the source region is arranged at two or more laterally opposite sides of the channel region. The drain region includes a low doped drift region and a highly doped region. A dopant concentration in the low doped drift region is at least one of smaller than a dopant concentration in the highly doped region and approximately zero. At least the low doped drift region is formed in the second semiconductor material.

### BRIEF DESCRIPTION OF DRAWINGS

The disclosure may be understood by reference to the following description taken in conjunction with the accompanying drawings, in which like reference numerals identify like elements, and in which:

FIGS. 1a and 1b show schematic views of portions of a semiconductor device according to an embodiment, wherein FIG. 1a shows a schematic top view and FIG. 1b shows a schematic cross-sectional view;

FIGS. 2a to 2d show schematic cross-sectional views of the portion of the semiconductor device shown in FIGS. 1a and 1 b in stages of a manufacturing process according to an embodiment;

FIG. 3 shows a schematic top view of a portion of a semiconductor device according to an embodiment;

FIG. 4 shows a schematic top view of a portion of a semiconductor device according to an embodiment;

FIG. 5 shows a schematic cross-sectional view of a portion of a semiconductor device according to an embodiment;

FIG. 6 shows a schematic cross-sectional view of a portion of a semiconductor device according to an embodiment; and

FIG. 7 shows a schematic top view of a semiconductor device according to an embodiment.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers'specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

According to embodiments disclosed herein, a second semiconductor material such as silicon carbide and/or silicon germanium that is different from a first semiconductor material of a substrate such as, for example, silicon is provided in an LDMOS transistor. In some embodiments, the entire source, drain and channel regions of the LDMOS transistor can be formed in the second semiconductor material. In other embodiments, a drain region of the LDMOS transistor, in particular a low doped drift region provided in the drain region that has a lower dopant concentration than a highly doped region provided in the drain region can be formed in the second semiconductor material, and source and channel regions can be formed in the first semiconductor material of the substrate. The second semiconductor material can be provided in a recess in the first semiconductor material. The recess can have a sigma shape that is obtainable by a crystallographically anisotropic etch process, or the recess can have rounded sidewalk, which are obtainable by forming the recess with an isotropic etch process. After the etching, the recess can be filled with silicon carbide or silicon germanium.

On the substrate, in addition to one or more LDMOS transistors, digital circuitry which can, for example, include a processor, a memory and/or an interface circuit, can be provided. The processor and/or the interface circuit can apply a gate voltage between the source region and a gate electrode of each LDMOS transistor for switching the LDMOS transistor between an OFF state and an ON state. A relatively high drain voltage that is greater than the gate voltage can be applied to the drain region of the LDMOS transistor. The drain voltage can be positive or negative, depending on whether the LDMOS transistor in an n-channel transistor or a p-channel transistor. An electrical current flowing through the LDMOS transistor in the ON state can be restricted by an electrical resistance of the low doped drain region.

Providing silicon carbide in the low doped drift region of the drain region of an LDMOS transistor can help to increase the resistance of the low doped drift region, and can have advantages concerning current density distribution in the LDMOS transistor. Furthermore, since silicon carbide has greater heat conductivity than silicon, providing silicon carbide in the low doped drift region can help to improve heat dissipation from the LDMOS transistor. Providing silicon germanium in the low doped drift region can also have advantages associated therewith, in particular in p-channel LDMOS transistors.

In embodiments, digital circuitry can be formed the same semiconductor substrate as the one or more LDMOS transistor. Field effect transistors of the digital circuitry can be formed in accordance with Very Large Scale Integration (VLSI) technology according to the 28 nm technology node or below, and techniques such as high-k metal gate techniques can be employed, wherein gate-first technologies, replacement gate technologies or hybrid processes can be used. In some embodiments, for forming transistors of the digital circuitry, processes such as full high-k metal gate replacement gate and 3-D device approaches can be employed.

Embodiments disclosed herein can have advantages associated therewith which include an increased breakdown voltage of the LDMOS transistors as well as an increased robustness and reliability and a better performance. Furthermore, a relatively high heat conductivity of the second semiconductor material can help to improve a dissipation of heat from the LDMOS transistors and to provide a desired resistivity of the low doped drift region in the drain region, which can help reduce a size of the LDMOS transistors.

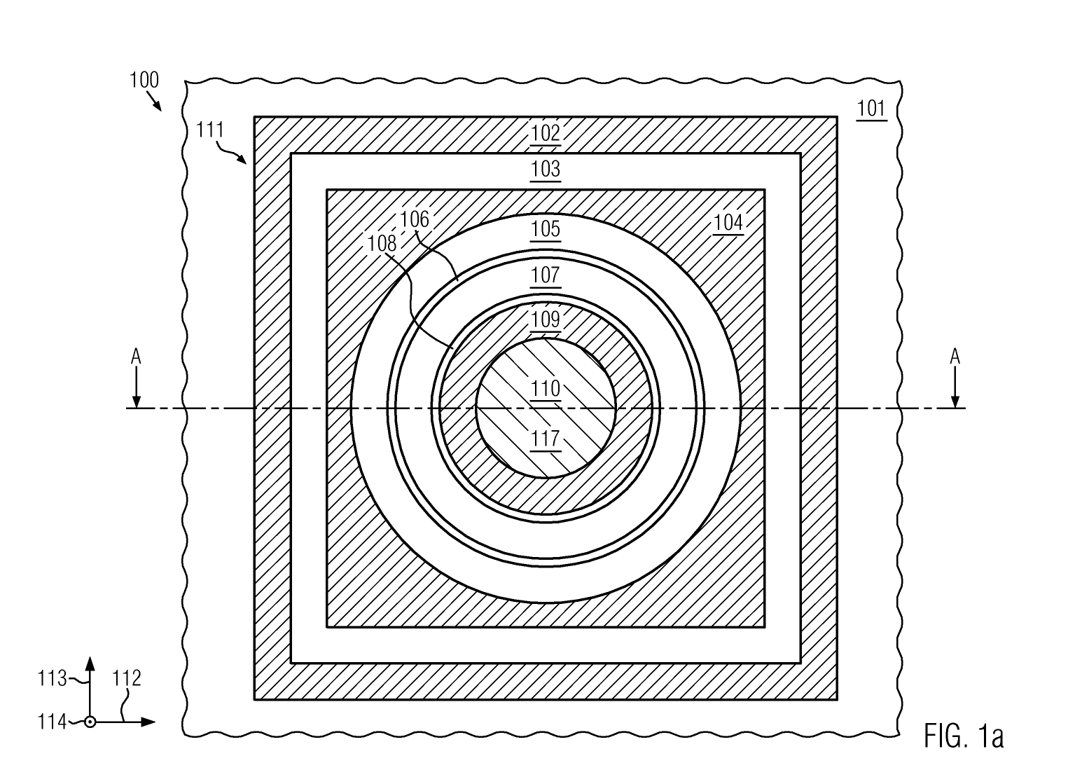

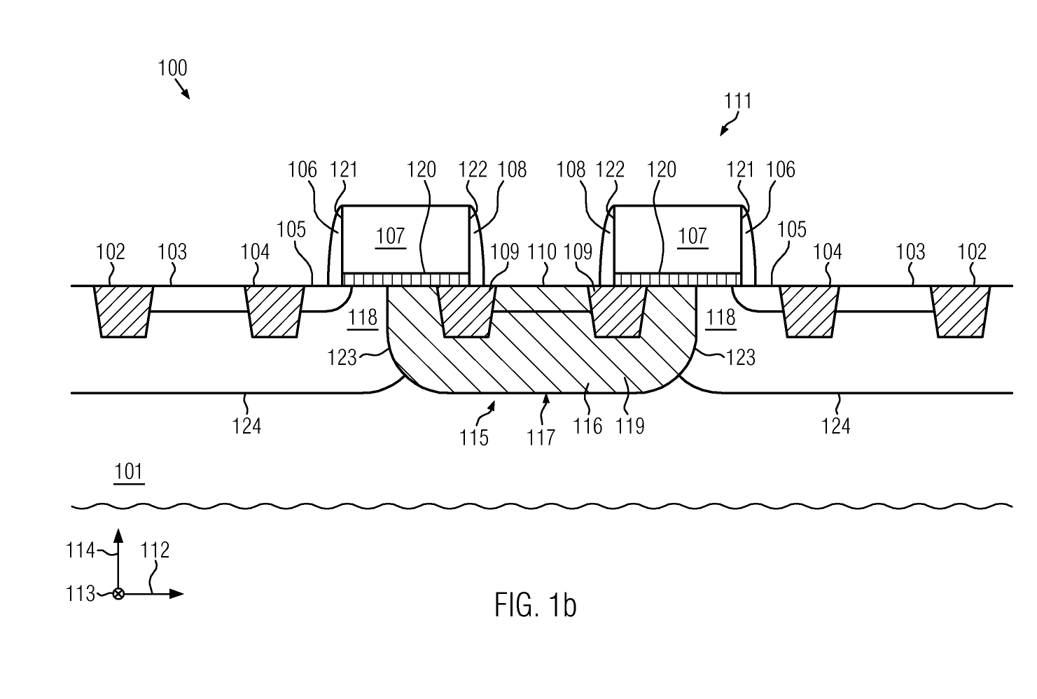

In the following, further embodiments will be described with reference to the figures. FIGS. 1a and 1b show schematic views of a portion of a semiconductor device 100 according to an embodiment. FIG. 1a shows a schematic top view of the portion of the semiconductor device 100, and FIG. 1b shows a schematic cross-sectional view along the line A-A. Reference numerals 112, 113 denote a first horizontal direction and a second horizontal direction, respectively, and reference numeral 114 denotes a vertical direction. In the view of FIG. 1a, the horizontal directions 112, 113 lie in the plane of drawing, and the vertical direction 114 extends perpendicularly to the plane of drawing, pointing towards the viewer, as indicated by a circle with a dot in the center. In the view of FIG. 1b, the first horizontal direction 112 and the vertical direction 114 lie in the plane of drawing, and the second horizontal direction 113 is perpendicular to the plane of drawing, pointing away from the viewer, as indicated by a circle with an “x” in the center.

The semiconductor device 100 includes a substrate 101. The substrate 101 can be a semiconductor substrate including a first semiconductor material. In embodiments, the substrate 101 can be a bulk semiconductor substrate, for example a wafer or die formed of the first semiconductor material. The first semiconductor material can include substantially pure silicon, wherein “substantially pure silicon” is to be understood as being different from compound semiconductor materials including silicon such as silicon carbide and/or silicon germanium, but including a presence of dopants and/or impurities.

The vertical direction 114 can be a thickness direction of the substrate 101, wherein an extension of the substrate 101 in the vertical direction 114 is smaller than any extension of the substrate 101 in any direction other than the vertical direction 114.

The semiconductor device 100 includes a recess 115. The recess 115 can be filled with a second semiconductor material that has a different composition than the first semiconductor material from which the substrate 101 is formed. In embodiments wherein the first semiconductor material is substantially pure silicon, the second semiconductor material can be a compound semiconductor material including silicon and a chemical element other than silicon, for example silicon germanium or silicon carbide.

In embodiments wherein the second semiconductor material is a compound semiconductor material including silicon, the second semiconductor material need not be a stoichiometric compound of silicon and the chemical element other than silicon. The content of the element other than silicon in the second semiconductor material 116 can be selected such that a desired intrinsic resistivity and/or heat conductivity of the second semiconductor material 116 is obtained.

In embodiments, the second semiconductor material 116 can be silicon carbide having a carbon content in a range from about 2% to about 15%. In other embodiments, the second semiconductor material 116 can be silicon germanium having a germanium content in a range from about 15% to about 50%.

In some embodiments, the composition of the second semiconductor material 116 can be substantially the same in the entire recess 115. In other embodiments, the composition of different portions of the second semiconductor material 116 can be different. For example, the composition of the second semiconductor material can have a profile along the vertical direction 114. In embodiments wherein the second semiconductor material 116 is a compound of silicon and a chemical element other than silicon, the content of the chemical element other than silicon in the second semiconductor material 116 can have a profile along the vertical direction 114. For example, the content of the chemical element other than silicon can be lower at the bottom of the recess 115.

The second semiconductor material 116 can include dopants, as will be described in more detail below.

The semiconductor device 100 includes a transistor 111. The transistor 111 can be a high voltage field effect transistor that is suitable for operation at a relatively high operating voltage that is applied between its source region and its drain region. The operating voltage of the transistor 111 can be in a range from about 3V to about 15V.

As shown in FIGS. 1a and 1b, the transistor 111 can be a Laterally Diffused Metal Oxide Semiconductor (LDMOS) transistor.

The transistor 111 includes a source region 105, a drain region 117, a gate electrode 107 and a channel region 118. The channel region 118 is provided below the gate electrode 107. A gate insulation layer 120 provides electrical insulation between the gate electrode 107 and portions of the semiconductor structure 100 that are arranged below the gate electrode 107 and which include, in particular, the channel region 118.

The source region 105 can be provided in a well region 124. Both the source region 105 and the well region 124 can be doped, wherein the doping of the source region 105 is inverse to a doping of the well region 124.

In some embodiments, the transistor 111 can be an n-channel transistor. In such embodiments, the source region 105 can be n-doped, and the well region 124 can be p-doped. In other embodiments, the transistor 111 can be a p-channel transistor. In such embodiments, the source region 105 can be p-doped, and the well region 124 can be n-doped.

The channel region 118 can be provided in the well region 124, and a doping of the channel region 118 can correspond to the doping of well region 124.

The source region 105, the channel region 118 and the well region 124 can be provided in the first semiconductor material of the substrate 101. The drain region 117 can be provided in the second semiconductor material 116 in the recess 115. An interface 123 between the drain region 117 and the channel region 118 can be defined by an interface between the first semiconductor material and the second semiconductor material at a sidewall of the recess 115.

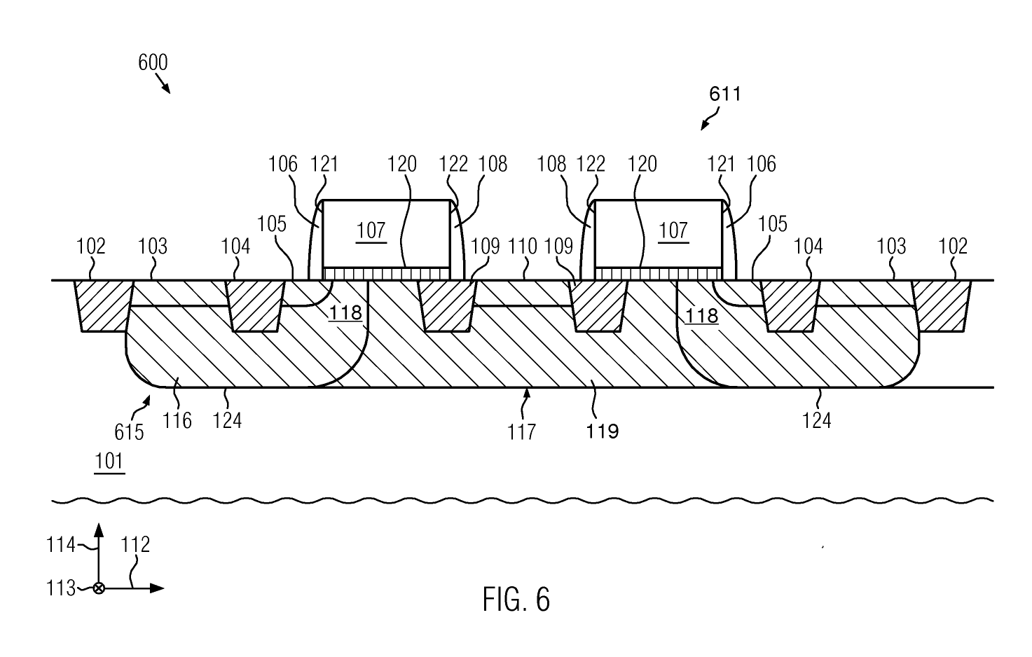

In other embodiments, the source region 115 and the channel region 118 can also be provided in the second semiconductor material. Examples of such embodiments will be described below with reference to FIG. 6.

The drain region 117 can include a low doped drift region 119 and a highly doped region 110. The low doped drift region 119 and the highly doped region 110 can be doped with a same type of dopant as the source region 105 wherein, however, a dopant concentration in the low doped drift region 119 is lower than a dopant concentration in the highly doped region 110. Hence, in embodiments wherein the transistor 111 is an n-channel transistor, the highly doped region 110 can have a relatively high concentration of an n-type dopant, and the low doped drift region 119 can include a relatively low concentration of an n-type dopant. In embodiments wherein the transistor 111 is a p-channel transistor, the highly doped region 110 can include a relatively high concentration of a p-type dopant, and the low doped drift region 119 can include a relatively low concentration of a p-type dopant. In other embodiments, the low doped drift region 117 can be substantially undoped, having a dopant concentration of approximately zero.

As can be seen from the cross-sectional view of FIG. 1b, portions of low doped drift region 119 can extend below the gate electrode 107. The highly doped region 110 can be located at a center of the drain region 117, and it can be at a distance to the gate electrode 107.

The drain region 117 can have an approximately circular shape (see FIG. 1a). The gate electrode 107 and the source region 105 can have an approximately circular ring shape. A shape of the channel region 118 can be defined by the shape of the gate electrode 107 below which it is provided, so that the channel region 118 has an approximately circular ring shape. However, a channel length of the transistor 111, being a difference between an outer radius and an inner radius of the channel region 118, can be smaller than a difference between an outer radius and an inner radius of the gate electrode, since portions of the low doped drift region 119 can extend below the gate electrode 107. The drain region 117, the channel region 118, the gate electrode 107 and the source region 105 can be substantially concentric with each other.

Thus, the channel region 118 is arranged at a plurality of laterally opposed sides of the drain region 117. In particular, the channel region 118 is arranged both at a side of the drain region 117 having relatively small values of a coordinate along the first horizontal direction 112 (on the left side of the drain region 117 in the top view of FIG. 1a and the cross-sectional view of FIG. 1b) and on a side of the drain region 117 laterally opposed thereto having relatively high values of a coordinate along the first horizontal direction 112 (on the right side of the drain region 117 in the views of FIGS. 1a and 1b). Moreover, the channel region 118 is arranged both at a side of the drain region 117 having relatively small values of a coordinate along the second horizontal direction 113 (below the drain region 117 in the top view of FIG. 1a) and at a side of the drain region 117 laterally opposed thereto having relatively high values of a coordinate along the second horizontal direction 113 (above the drain region 117 in the view of FIG. 1a).

Similarly, due to the approximately circular ring shape of the source region 105, the source region 105 is arranged at a plurality of laterally opposite sides of the channel region 118.

In embodiments wherein the source region 105 and the channel region 118 have an approximately circular ring shape, the channel region 118 extends all around the drain region 117, and the source region 105 extends all around the channel region 118 and the drain region 117.

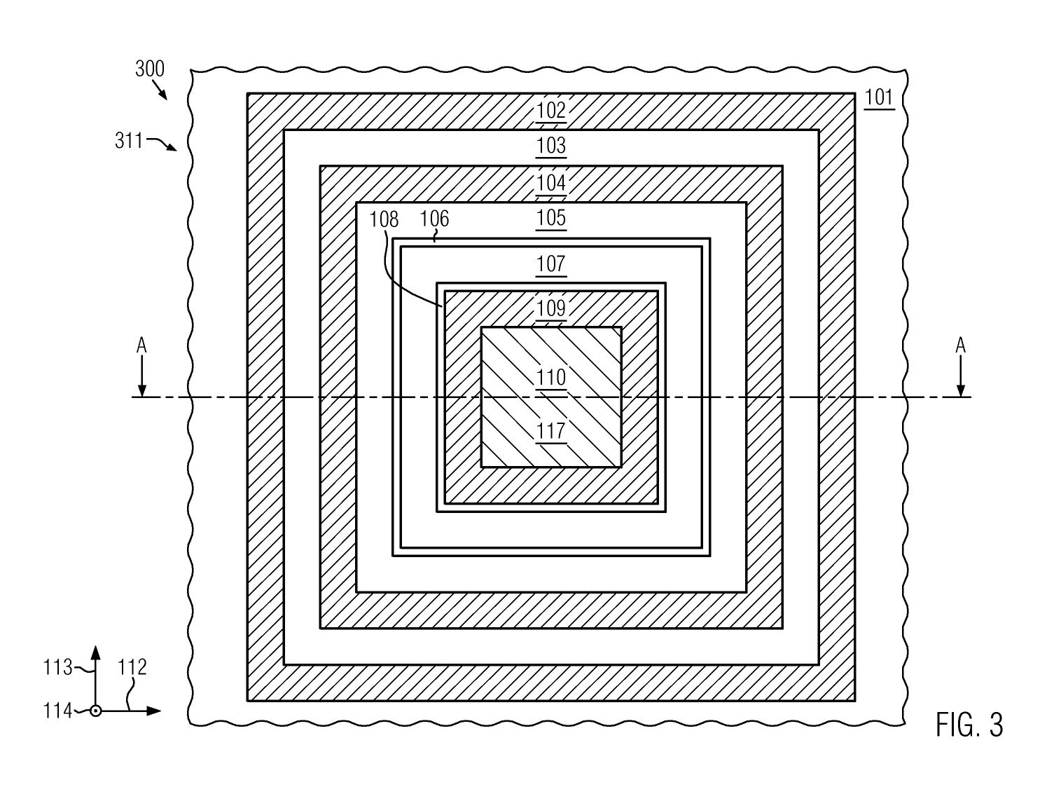

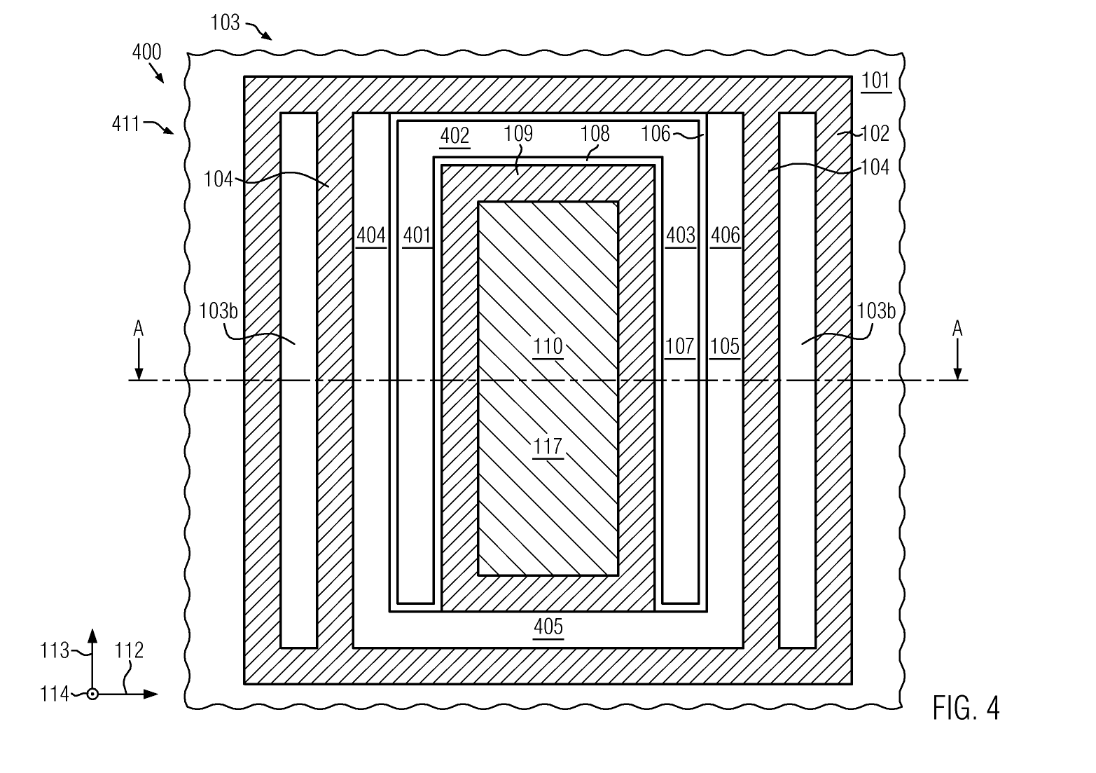

The present disclosure is not limited to embodiments wherein the drain region 117 has an approximately circular shape, and wherein each of the gate electrode 107 and the source region 105 has an approximately circular ring shape, as shown in FIG. 1a. Examples of alternative shapes of the drain region 117, the gate electrode 107 and the source region 105 will be described below with reference to FIGS. 3 and 4.

In addition to the features described above, the transistor 111 can include a substrate contact region 103. The substrate contact region 103 can be provided in the well region 124 and can be doped oppositely to the doping of the source region 105, so that the type of dopant in the source contact region 103 and the p-well region 124 is identical. In embodiments wherein the transistor 111 is an n-channel transistor, the substrate contact region 103 can be p-doped, and in embodiments wherein the transistor 111 is a p-channel transistor, the substrate contact region 103 can be n-doped.

As shown in the top view of FIG. 1a, in embodiments, the source contact region 103 can have an approximately rectangular annulus shape, in particular an approximately square annulus shape, extending all around the source region 105, the channel region 118 and the drain region 117. In other embodiments, the source contact region 103 can have an approximately circular ring shape that is concentric with the drain region 117, the channel region 118, the gate electrode 107 and the source region 105.

The transistor 111 can further include a shallow trench isolation 104 providing electrical insulation between the substrate contact region 103 and the source region 105.

Additionally, the transistor 111 can include a shallow trench isolation 109. The shallow trench isolation 109 can be arranged below an inner edge 122 of the gate electrode 107 facing the drain region 117. The shallow trench isolation 109 can enclose the highly doped region 110 of the drain region 117 and can provide an additional electrical insulation between the highly doped region 110 and the gate electrode 107, in addition to the electrical insulation between the gate electrode 107 and the drain region 117 provided by the gate insulation layer 120. The shallow trench isolation 109 can help to reduce electrical fields at the inner edge 122 of gate electrode 107, which can help to increase a robustness of the transistor 111 with respect to relatively high voltage differences between the gate electrode 107 and the highly doped region 110 of the drain region 117.

The low doped drift region 119 can be provided in another part of the second semiconductor material 116 in the recess 115 than the highly doped region 110, wherein the low doped drift region 119 extends below the highly doped region 110 and shallow trench isolation 109. Additionally, as shown in the schematic cross-sectional view of FIG. 1b, portions of the second semiconductor material 116 and the low doped drift region 119 can extend below the gate electrode 107, so that the interface 123 between the low doped drift region 119 and the channel region 118 is located below the gate electrode 107. A shape of the interface 123 between the low doped drift region 119 and the channel region 118 can correspond to a shape of the recess 115 in the first semiconductor material of the substrate 101.

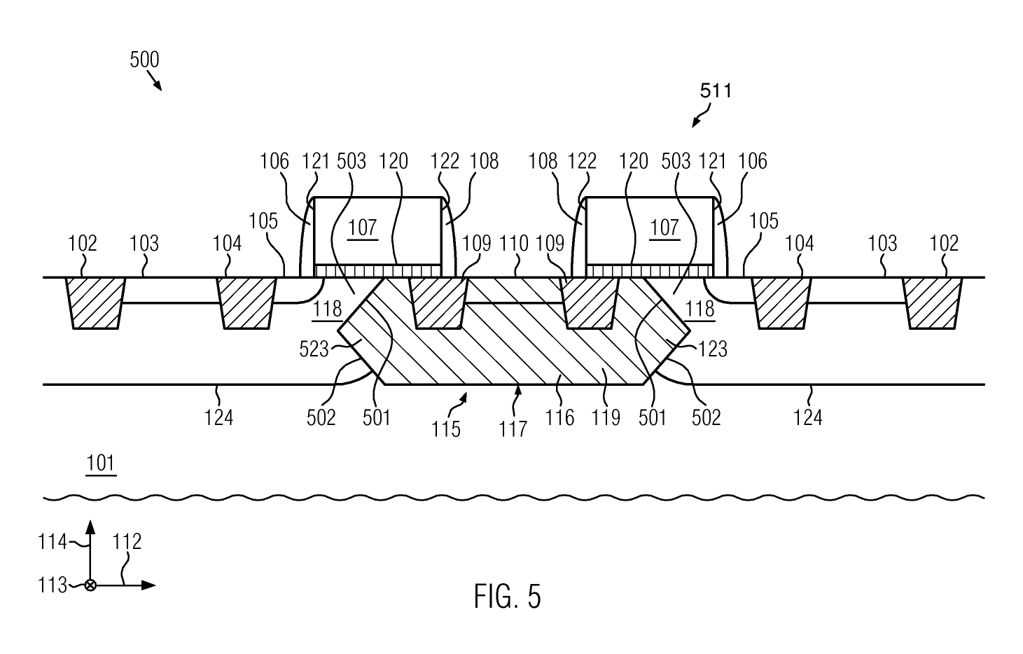

As shown in FIG. 1b, in embodiments, the interface 123 between the low doped drift region 119 and the channel region 118 can have a rounded shape, as obtainable by forming the recess 115 with a substantially isotropic etch process, as detailed below. The present disclosure, however, is not limited to embodiments wherein the interface 123 between the low doped drift region 119 and the channel region 118 has a rounded shape. Alternative shapes of the interface 123 between the low doped drift region 119 and the channel region 118 will be described below with reference to FIG. 5.

The semiconductor structure 100 can further include a shallow trench isolation 102 extending all around the transistor 111 and providing electrical insulation between the transistor 111 and other circuit elements of the semiconductor structure 100.

The shallow trench isolations 102, 104, 109 can include an electrically insulating material such as, for example, silicon dioxide, that is provided in trenches. The shallow trench isolation 102 and the shallow trench isolation 104 can be provided in trenches in the first semiconductor material of the substrate 101. The shallow trench isolation 109 below the inner edge 122 of the gate electrode 107 can be provided in a trench in the second semiconductor material 116, wherein a depth of the trench of the shallow trench isolation 109 is smaller than a depth of the recess 115 wherein the second semiconductor material 116 is provided so that the second semiconductor material 116 extends below the shallow trench isolation 109. A depth of the highly doped region 110 of the drain region 117 can be smaller than a depth of the shallow trench isolation 109.

An interface between the source region 105 and the channel region 118 can be arranged near an outer edge 121 of the gate electrode 107 facing the source region 105. In some embodiments, the interface between the source region 105 and the channel region 118 can be substantially aligned with the outer edge 121 of the gate electrode 107. In other embodiments, a portion of the source region 105 can extend below the gate electrode 107.

At the outer edge 121 of the gate electrode 107, an outer sidewall spacer 106 of the gate electrode 107 can be provided. At the inner edge 122 of the gate electrode 107, an inner sidewall spacer 108 can be provided. The sidewall spacers 106, 108 can be formed of one or more electrically insulating materials such as silicon dioxide, silicon nitride and/or silicon oxynitride. Features of the sidewall spacers 106, 108 can correspond to those of sidewall spacers conventionally formed at gate electrodes of field effect transistors in integrated circuits.

In some embodiments, the gate insulation layer 120 can be formed of substantially pure silicon dioxide. In other embodiments, the gate insulation layer 120 can include a high-k material having a greater dielectric constant than silicon dioxide, in particular a dielectric constant greater than about 4. For example, the gate insulation layer 120 can include one or more materials selected from the group of materials including hafnium dioxide, zirconium dioxide, hafnium silicate and zirconium silicate. In some embodiments, the gate insulation layer 120 can include a number of sublayers formed of different materials, for example a sublayer of silicon dioxide at an interface between the gate insulation layer 120, the channel region 118 and low doped drift region 119, and a sublayer including a high-k material provided on the silicon dioxide sublayer.

In some embodiments, in particular in embodiments wherein the gate insulation layer 120 includes substantially pure silicon dioxide, the gate electrode 107 can be formed of polysilicon. In embodiments wherein the gate insulation layer 120 includes a high-k material, the gate electrode 107 can include a metal. In some embodiments, the entire gate electrode 107 can be formed of a metal. Alternatively, a portion of the gate electrode 107 at an interface between the gate electrode 107 and the gate insulation layer 120 can be formed of a metal, and an upper portion of the gate electrode 107 can be formed of polysilicon.

In embodiments wherein the gate electrode 107 includes a metal, the metal can be selected in accordance with the type of the transistor 111. In embodiments wherein the transistor 111 is an n-channel transistor, the metal can include lanthanum, lanthanum nitride and/or titanium nitride. In embodiments wherein the transistor 111 is a p-channel transistor, the metal can include aluminum and/or aluminum nitride.

Features of the low doped drift region 119 can have an influence on features of the transistor 111. In particular, features of the low doped drift region 119 can influence a breakdown voltage of the pn-transition between the channel region 118 and the drain region 117. In the OFF state of the transistor 111, the pn-transition between the channel region 118 and the drain region 117 is biased in the reverse direction by the operating voltage of the transistor 111 that is applied between the source region 105 and the drain region 117, so that the breakdown voltage of the pn-transition is related to the suitability of the transistor 111 for being operated at a relatively high target operating voltage.

The breakdown voltage of the pn-transition between the channel region 118 and the drain region 117 can depend on a dopant concentration in the low doped drift region 119, a distribution of dopants in the low doped drift region 119, on material properties of the second semiconductor material 116 wherein the low doped drift region 119 is provided, and on features of the heterojunction between the first semiconductor material of the channel region 118 and the second semiconductor material 116 at the interface 123 between the low doped drift region 119 and the channel region 118. Accordingly, providing the low doped drift region 119 in the second semiconductor material 116 can help to provide an increased breakdown voltage of the pn-transition between the channel region 118 and the low doped drift region 119, allowing a greater operating voltage of the transistor 111 and/or reducing a size of the transistor 111 when maintaining a predetermined breakdown voltage of the pn-transition.

When the transistor 111 is operated at its target operating voltage, the current flowing between the source region 105 and the drain region 117 in the ON state of the transistor 111 can depend on the electrical resistance of the low doped drift region 119. In some situations, for example when there is a relatively low impedance of an electrical path between the transistor 111 and a power source connected between the source region 105 and the drain region 117, a current through the transistor 111 can be limited by the resistance of the low doped drift region 119.

To avoid a destruction of the transistor 111 and/or other portions of the semiconductor device 100 in such situations, it can be desirable to provide a relatively high resistance of the low doped drift region 119. The resistance of the low doped drift region 119 can depend on the resistivity of the second semiconductor material 116. Using a second semiconductor material 116 having a relatively high intrinsic resistivity can help to increase the resistance of the low doped drift region 119 at a particular size and shape of the low doped drift region 119 compared to implementations wherein the low doped drift region 119 is provided in substantially pure silicon and/or can allow a reduction of the size of the transistor 111 while maintaining a particular value of the resistance of the low doped drift region 119.

The performance of the transistor 111 can also depend on a heat conductivity of the second semiconductor material 116 wherein the low doped drift region 119 is provided. A greater heat conductivity of the second semiconductor material 116 can help to improve a dissipation of heat created by a current flowing through the electrically resistive low doped drift region 119.

Compared to substantially pure silicon, silicon carbide can provide a greater band gap, which can be of advantage for providing a high breakdown voltage of the pn-transition between the channel region 118 and the low doped drift region 119. Furthermore, silicon carbide can provide a greater intrinsic resistivity than substantially pure silicon, as well as a better heat conductivity. Accordingly, using silicon carbide as the second semiconductor material 116 wherein the low doped drift region 119 is provided can be particularly advantageous from the point of view of improving the performance of the transistor 111.

Using silicon germanium as the semiconductor material 116 wherein the low doped drift region 119 is provided can also be advantageous, due to the presence of the heterojunction at the interface 123 between the channel region 118 and the low doped drift region 119 and possibilities to optimize features of the transistor 111 by adapting a germanium concentration and/or a distribution of germanium in the low doped drift region 119.

In some embodiments, the semiconductor device 100 can include a plurality of transistors similar to transistor 111. The plurality of transistors can include n-channel transistors as well as p-channel transistors. In some embodiments, in the n-channel transistors, silicon carbide can be used as the second semiconductor material 116, and silicon germanium can be used as the second semiconductor material 116 in the p-channel transistors. In other embodiments, silicon carbide can be used both in n-channel transistors and p-channel transistors. In some embodiments, a dopant concentration in the low doped drift region 119 can vary along the vertical direction 114, which can provide further possibilities for optimizing the low doped drift region 119.

In other embodiments, the dopant concentration in substantially the entire low doped drift region 119 can be approximately equal, or the entire low doped drift region 119 can be substantially undoped.

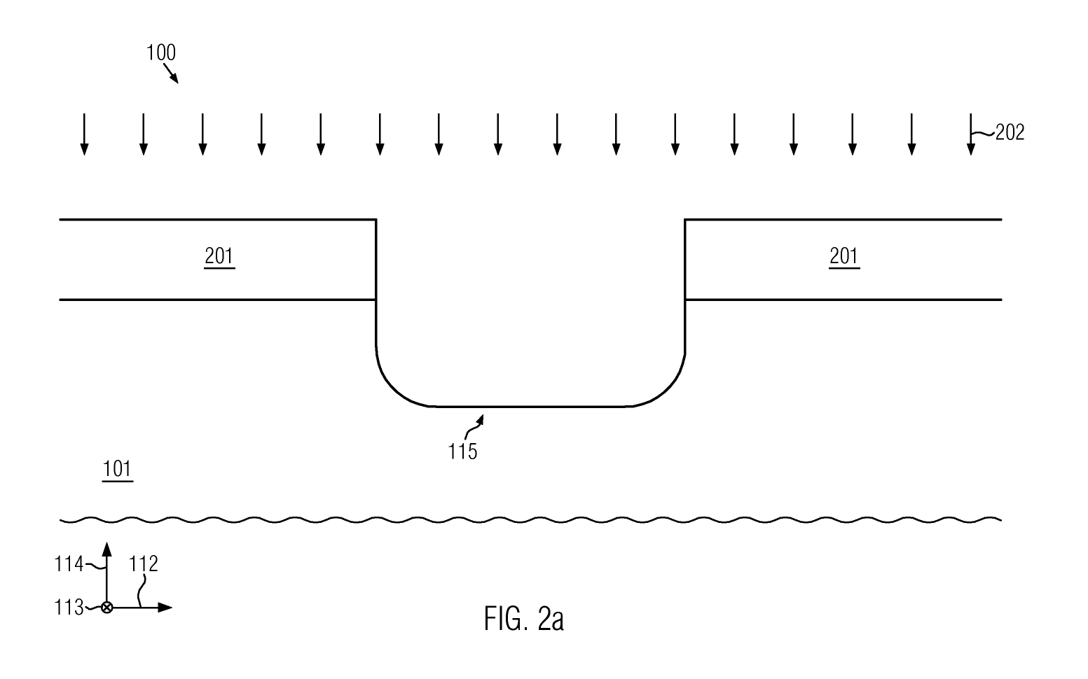

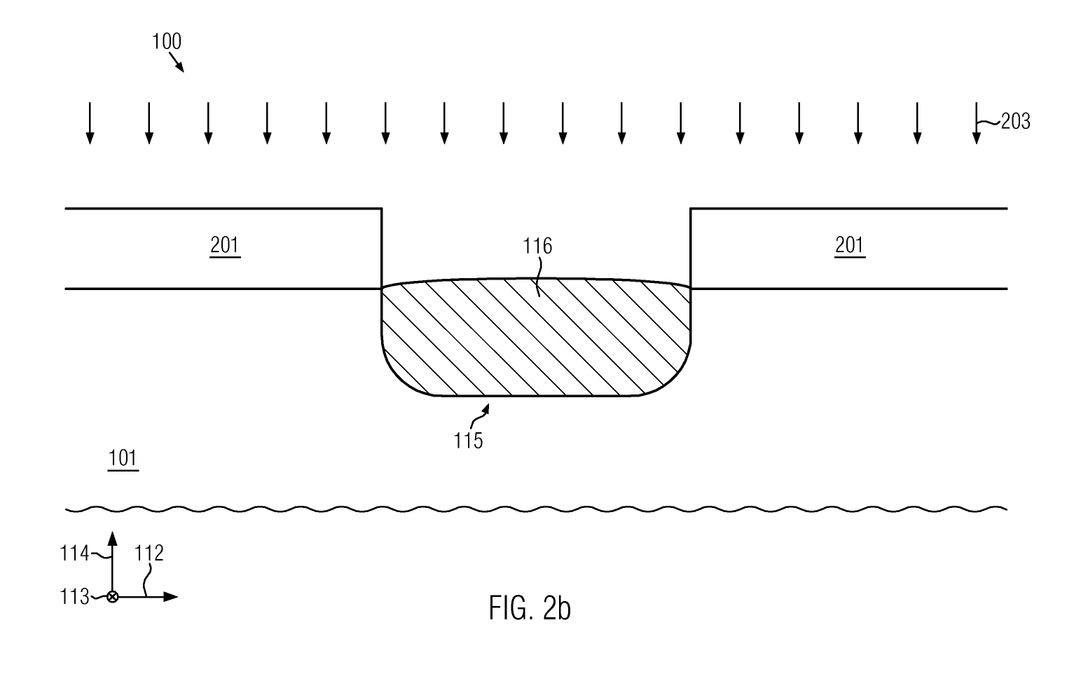

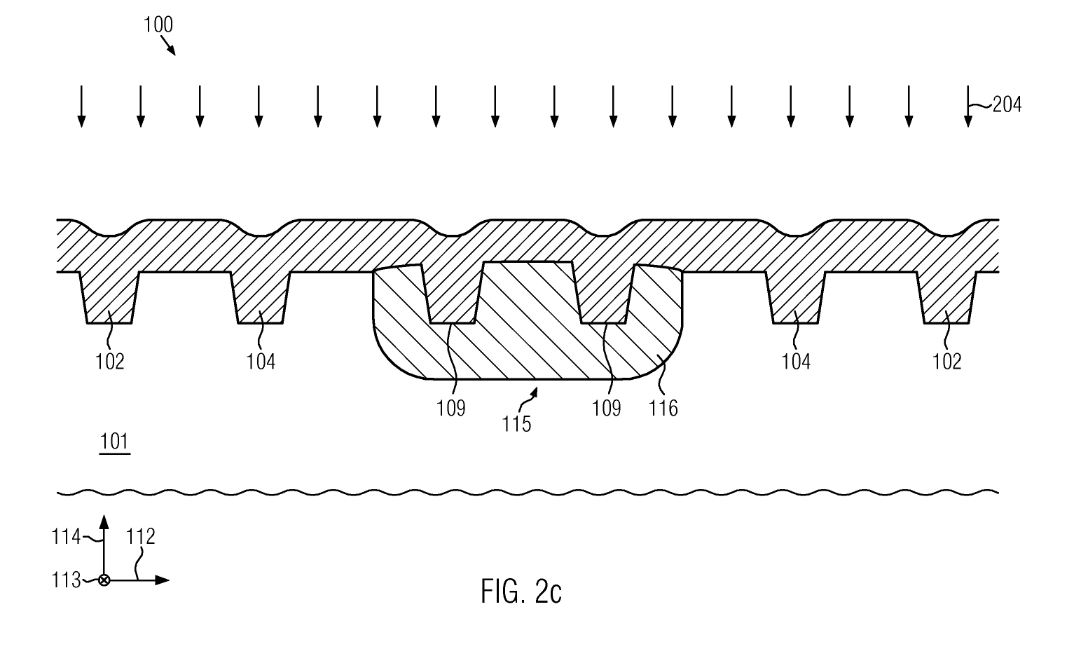

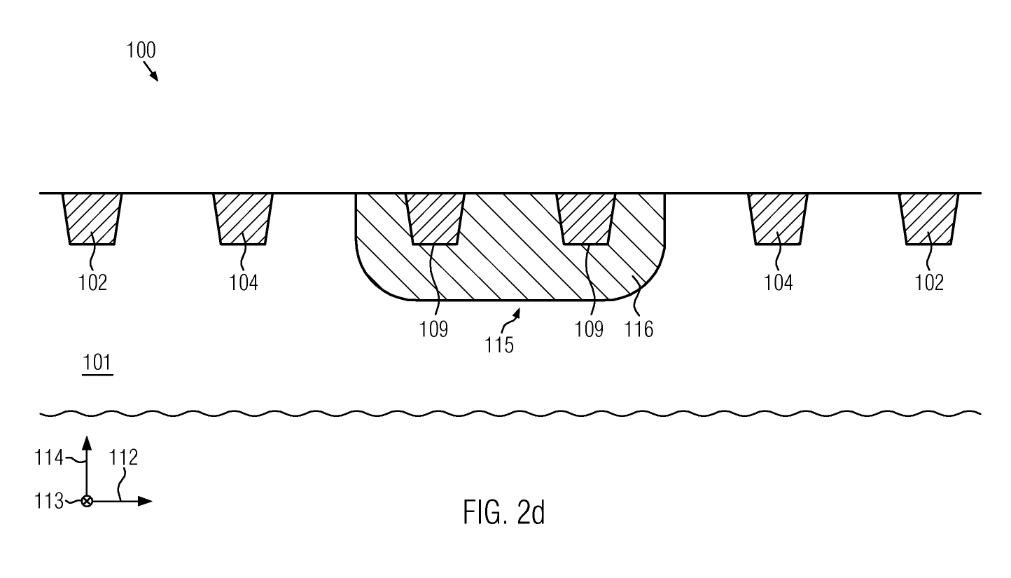

In the following, methods of forming the semiconductor device 100 will be described with reference to FIGS. 2a to 2d.

FIG. 2a shows a schematic cross-sectional view of the portion of the semiconductor device 100 wherein the transistor ill is to be formed in a first stage of the manufacturing process. The portion of the semiconductor structure 100 shown in FIG. 2a corresponds to the portion of the semiconductor device 100 shown in FIGS. 1a and 1b, and the plane of the cross-section of FIG. 2a corresponds to the plane of the cross-section of FIG. 1b.

The manufacturing process can include providing the semiconductor substrate 101 including the first semiconductor material, for example in form of a wafer or die of substantially pure silicon. Thereafter, a hardmask 201 can be formed over the substrate 101. The hardmask 201 has an opening at a location wherein the recess 115 is to be formed and covers other portions of the substrate 101. In embodiments, the hardmask 201 can be formed of silicon dioxide, silicon oxynitride and/or silicon nitride.

The hardmask 201 can be formed using conventional techniques including a formation of a layer of a hardmask material using techniques of oxidation, chemical vapor deposition and/or plasma-enhanced chemical vapor deposition, and patterning the layer of hardmask material using techniques of photolithography and etching.

After the formation of the hardmask 201, an etch process can be performed, as schematically denoted by arrows 202 in FIG. 2a. In the etch process, the semiconductor structure 100 can be exposed to an etchant adapted to remove the first semiconductor material of the substrate 101, leaving the hardmask 201 substantially intact. Therefore, at the location of the opening of the hardmask 201, a portion of the first semiconductor material of the substrate 101 can be removed, so that the recess 115 is formed. Portions of the substrate 101 which are covered by the hardmask 201 are protected from being affected by the etchant by the hardmask 201.

In embodiments, the etch process 201 can be a substantially isotropic etch process, for example a substantially isotropic plasma etch process for etching silicon. Features of the etch process 202 can correspond to those of conventional substantially isotropic etch processes for etching silicon. In other embodiments, a wet etch process wherein the semiconductor device 100 is exposed to a wet chemical etchant adapted to substantially isotropically remove silicon, for example a mixture of hydrofluoric acid and nitric acid, can be used.

The present disclosure is not limited to embodiments wherein the etch process 202 is substantially isotropic. Other embodiments, wherein a crystallographically anisotropic etch process is employed, will be described below with reference to FIG. 5.

FIG. 2b shows a schematic cross-sectional view of the semiconductor device 100 in a later stage of the manufacturing process.

After the formation of the recess 115, the recess 115 can be filled with the second semiconductor material 116. This can be done by means of a deposition process, as schematically denoted by reference numeral 203 in FIG. 2b. In embodiments, the hardmask 201 can remain on the substrate 101 during the deposition process 203.

The deposition process 203 can be a selective epitaxial growth process adapted for the deposition of the second semiconductor material 116. In embodiments, the deposition process 203 can be a physical vapor deposition process, chemical vapor deposition process or a plasma enhanced chemical vapor deposition process, wherein parameters of the deposition process 203 are adapted such that a growth of the second semiconductor material 116 can occur on the first semiconductor material of the substrate 101 and on portions of the second semiconductor material 116 already deposited in the recess 115, whereas substantially no second semiconductor material or only a small amount of the second semiconductor material is deposited on the hardmask 201.

In some embodiments, parameters of the deposition process 203 such as, for example, composition and/or pressure of a reactant gas used, temperature of the semiconductor device 100 and, in embodiments wherein the deposition process 203 is a plasma enhanced chemical vapor deposition process, a plasma power applied can be varied so that a variation of the composition of the deposited second semiconductor material 116 is obtained. Thus, a profile of the composition of the second semiconductor material 116 along the vertical direction 114 as described above can be obtained. For example, in embodiments wherein the second semiconductor material 116 includes a compound of silicon and a chemical element other than silicon such as carbon or germanium, a profile of the content of the chemical element other than silicon in the second semiconductor material 116 along the vertical direction 114 can be obtained by varying parameters of the deposition process 203 during the deposition process 203.

In embodiments, the second semiconductor material 116 can be in situ doped during the deposition process 203. This can be done by supplying a chemical compound including a dopant such as boron or arsenic during the deposition process 203. By varying the amount of the chemical compound including the dopant during the deposition process 203, a dopant profile along the vertical direction 114 can be obtained.

In other embodiments, the deposition process 203 can be adapted to deposit substantially undoped second semiconductor material 116.

Further features of the deposition process 203 can correspond to those of conventional selective epitaxial growth processes for depositing silicon carbide and/or silicon germanium.

FIG. 2c shows a schematic cross-sectional view of the semiconductor device 100 in a later stage of the manufacturing process.

After the deposition process 203, the hardmask 201 can be removed, for example by means of an etch process.

In some embodiments, a plurality of steps including a formation of a hardmask, a formation of a recess and/or a deposition as described above can be performed for providing different second semiconductor materials in n-channel and p-channel transistors wherein, after each step, the hardmask used in the preceding step can be removed by an etch process.

Thereafter, the shallow trench isolation regions 102, 104, 109 can be formed. This can be done by forming trenches having shapes corresponding to those of the desired shapes of the shallow trench isolation regions 102, 104, 109 as described above and filling the trenches with an electrically insulating material as silicon dioxide.

The trenches can be formed by means of techniques of photolithography and etching. Filling the trenches with the electrically insulating material can be done by means of a deposition process as schematically denoted by arrows 204 in FIG. 2c. The deposition process 204 can be a conventional chemical vapor deposition process or plasma enhanced chemical vapor deposition process adapted for the deposition of the electrically insulating material of the shallow trench isolations 102, 104, 109.

After the deposition of the electrically insulating material of the shallow trench isolations 102, 104, 109, a planarization process can be performed. The planarization process can include a chemical mechanical polishing process. In the planarization process, portions of the electrically insulating material deposited outside the trenches of the shallow trench isolations 102, 104, 109 can be removed, and a substantially planar surface of the semiconductor device 100 can be obtained, as shown in FIG. 2d.

After the chemical mechanical polishing process, ion implantation processes can be performed for introducing a dopant into the well region 124. Then, the gate insulation layer 120 and the gate electrode 107 can be formed by depositing layers of materials of the gate insulation layer 120 and the gate electrode 107 and patterning these layers by means of processes of photolithography and etching. Then, further ion implantation processes can be performed for introducing dopants into the highly doped region 110 of the drain region 117 and/or the source region 105. Moreover, the sidewall spacers 121, can be formed adjacent the gate electrode 107 by substantially isotropically depositing a layer of a material of the sidewall spacers 121, 122 and then performing an anisotropic etch process to remove portions of the layer of sidewall spacer material from other locations than the edges 121, 122 of the gate electrode 107. Thereafter, further ion implantation processes for implanting dopants into the source region 105, the highly doped region 110 of the drain region 117 and the substrate contact region 103 can be performed. During each of the above described ion implantation processes, masks can be used for avoiding an introduction of dopants into portions of the semiconductor device 100 which are not to be doped.

The present disclosure is not limited to embodiments wherein the gate electrode 107 and the gate insulation layer 120 are formed by means of a gate first approach as described above. In other embodiments, replacement gate approaches or hybrid approaches, wherein some of a plurality of transistors of the semiconductor device 100 are formed using a gate first approach and other transistors are formed using a replacement gate approach can be used.

In the following, further embodiments will be described with reference to FIGS. 3 to 6. For convenience, in FIGS. 1a, 1b and 2a to 2d, on the one hand, and in FIGS. 3 to 6, on the other hand, like reference numerals have been used to denote like components. Unless explicitly stated otherwise, features shown in any of FIGS. 3 to 6 can have properties corresponding to those of features shown in FIGS. 1a, 1b and 2a to 2d denoted by like reference numerals, and corresponding methods can be used for the formation thereof.

FIG. 3 shows a schematic top view of a semiconductor device 300 according to an embodiment. The semiconductor device 300 includes an LDMOS transistor 311. A cross section of the transistor 311 along a line A-A can correspond to the cross section of the transistor 111 shown in FIG. 1b.

The transistor 311 includes a drain region 111 that is provided in a second semiconductor material having a different composition than a first semiconductor material of a substrate 101 on which the transistor 311 is provided. The drain region 117 includes a highly doped region 110 and a low doped drift region (not visible in the top view of FIG. 3) which is provided below the highly doped region 110 and has a lower dopant concentration than the highly doped region 110. The transistor 311 further includes a shallow trench isolation 109 around the highly doped region 110, a gate electrode 107, a source region 105 and a channel region below the gate electrode 107 (not visible in the top view of FIG. 3), a substrate contact region 103 and a shallow trench isolation 104 between the source region 105 and the substrate contact region 103. A further shallow trench isolation 102 can provide electrical insulation between the transistor 311 and other circuit elements of the semiconductor device 300. At edges of the gate electrode 107, sidewall spacers 106, 108 can be provided.

In the embodiment of FIG. 3, the drain region 117 has an approximately rectangular shape. Each of the shallow trench isolation 109, the gate electrode 107, the channel regio the source region 105, the substrate contact region 103 and the shallow trench isolations 102, 104 has an approximately rectangular annulus shape. Sides of the approximately rectangular shape of the gate electrode 117 and the rectangular annular shapes of the shallow trench isolations 102, 104, 109, the gate electrode 107, the source region 105 and the channel region can be substantially parallel to a first horizontal direction 112 or a second horizontal direction 113.

Thus, the channel region is arranged at laterally opposite sides of the drain region, having portions on two laterally opposite sides of the drain region 117 which are spaced apart along the first horizontal direction 102, and further portions on laterally opposite sides of the drain region 117 which are spaced apart along the second horizontal direction 113. Similarly, the source region 105 has portions on laterally opposed sides of the channel region which are spaced apart along the first horizontal direction 112, and further portions on laterally opposite sides of the channel region that are spaced apart along the second horizontal direction 113. Moreover, due to the approximately rectangular annulus shape of the channel region and the source region 105, the channel region extends all around the drain region 117, and the source region 105 extends all around the channel region and the drain region 117.

The configuration of transistor 311 provides an alternative to the configuration of transistor 111 described with reference to FIGS. 1a, 1b and 2a to 2d which has approximately circularly shaped and approximately circularly ring-shaped, respectively, source, channel and drain regions.

FIG. 4 shows a schematic top view of a portion of a semiconductor device 400 according to an embodiment including an LDMOS transistor 411. A cross-section of the transistor 411 along a line A-A can correspond to the cross-section shown in FIG. 1b. The transistor 411 has a drain region 117 including a highly doped region 110, and a low doped drift region (not visible in the top view of FIG. 4). The highly doped region 110 and the low doped drift region of the drain region 117 can be provided in a recess in a substrate 101 that is lilted with a second semiconductor material having a different composition than a first semiconductor material of the substrate 101. The low doped drift region can extend below the highly doped region 110 and a shallow trench isolation 109 around the highly doped region 110.

The transistor 411 can further include a gate electrode 107. The gate electrode 107 can have sidewall spacers 106, 108 which can be contiguous with each other. The transistor 411 further includes a source region 105, a channel region below the gate electrode 107 and a substrate contact region 103, which, in the embodiment of FIG. 4, is provided in form of two non-contiguous portions 103a, 103b. Additionally, shallow trench isolations 102, 104 can be provided.

In the transistor 411, the gate electrode 107 has an approximately U-shaped configuration. The source region 105 also has an approximately U-shaped configuration, having a greater width along the first horizontal direction 112 than the U-shape of the gate electrode 107, and being oppositely oriented with respect to the second horizontal direction 113.

Thus, the gate electrode 107 has portions 401, 403 arranged at laterally opposite sides of the drain region 117 which are spaced apart along the first horizontal direction 112 and a further portion 402 connecting the portions 401, 403. The channel region of the transistor 411 can be provided below the portions 401, 403 of the gate electrode 107, so that the channel region is arranged at two laterally opposite sides of the drain region 117.

The source region 105 has portions 404, 406, which are arranged on two laterally opposite sides of the channel region below the portions 401, 403 of the gate electrode and spaced apart along the first horizontal direction 112. Additionally, the source region 105 includes a portion 405 connecting the portions 404 and 406, which is arranged on a side of the drain region 117 laterally opposite the portion 402 of the gate electrode 107. The portion 404 of the source region 105 is arranged adjacent the portion 401 of the gate electrode 107, and the portion 406 of the source region 105 is arranged adjacent the portion 403 of the gate electrode 107.

The configuration of the transistor 411 shown in FIG. 4 provides a further alternative to the configurations of the transistors 111, 311 described above with reference to FIGS. 1a to 3.

FIG. 5 shows a schematic cross-sectional view of a portion of a semiconductor device 500 including an LDMOS transistor 511 according to an embodiment.

The transistor 511 has a drain region 117 provided in a recess 115 that is formed in a first semiconductor material of a substrate 101. The recess 115 is filled with a second semiconductor material 116 having a different composition than the first semiconductor material. The drain region 117 includes a highly doped region 110 and a low doped drift region 119. A sidewall of the recess 115 provides an interface 523 between the low doped drift region 119 and a channel region 118 of the transistor 511. The interface 523 has a sigma shape and includes a first portion 501 and a second portion 502, wherein the second portion 502 is arranged below the first portion 501, at a greater distance to a gate insulation layer 120 and a gate electrode 107 of the transistor 511.

The first portion 501 of the interface 123 is inclined inwardly with respect to the recess 115, so that the channel region 118 includes an overhang 503 that is arranged above a portion of the lightly doped drift region 119 located below the first portion 501 of the interface 123. The second portion 502 of the interface 123 is inclined outwardly with respect to the recess 115. At a boundary between the portions 501, 502 of the interface 123, the interface 123 can have a relatively sharp edge. Thus, in a cross-sectional view as shown in FIG. 5, the interface 123 has a shape similar to that of the Greek letter “Σ”. Similar to the transistors 111, 311, 411, described above with reference to FIGS. 1a to 4, the transistor 511 can further include a well region 124, shallow trench isolations 102, 104, 109, a source region 105, a substrate contact region 103 and sidewall spacers 106, 108.

For forming a recess 115 as shown in FIG. 5, an etch process similar the etch process 202 described above with reference to FIG. 2a can be performed wherein, however, different from the substantially isotropic etch process 202 of FIG. 2a, the etch process is crystallographically anisotropic. For performing a crystallographically anisotropic etch process, the substrate 101, being covered by a mask similar to hardmask 201 as described above with reference to FIG. 2a, can be exposed to an etchant adapted for performing a crystallographically anisotropic etch of the first semiconductor material of the substrate 101. In embodiments wherein the first semiconductor material includes substantially pure silicon, in the crystallographically anisotropic etch process, an etch chemistry including tetramethylammoniumhydroxide (TMAH) can be used.

FIG. 6 shows a schematic cross-sectional view of a semiconductor device 600 according to an embodiment. The semiconductor device 600 includes an LDMOS transistor 611. The LDMOS transistor 611 includes a recess 615 provided in a first semiconductor material of a substrate 101 and being filled with a second semiconductor material 116 having a different composition than the first semiconductor material of the substrate 101.

In the transistor 611, each of a drain region 117, a channel region 118, a source region 105 and a substrate contact region 103 are provided in the second semiconductor material 116 in the recess 615. The drain region 117 includes a highly doped region 110 and a low doped drift region 119, which are doped oppositely to a well region 124 wherein the channel region 118 is provided. The source region 105 and the substrate contact region 103 can be provided by appropriately doping portions of the second semiconductor material 116, wherein the type of dopant in the source region 105 corresponds to the type of dopant in the drain region 117, and the type of dopant of the substrate contact region 103 corresponds to the type of dopant in the well region 124. Additionally, the transistor 611 can include a gate insulation layer 120, agate electrode 107, sidewall spacers 106, 108 and shallow trench isolations 102, 104, 109.

When seen in a top view, each of the transistors 511, 611 can have a configuration as described above with reference to FIG. 1a or, in other embodiments, a configuration as described above with reference to FIG. 3 or a configuration as described above with reference to FIG. 4.

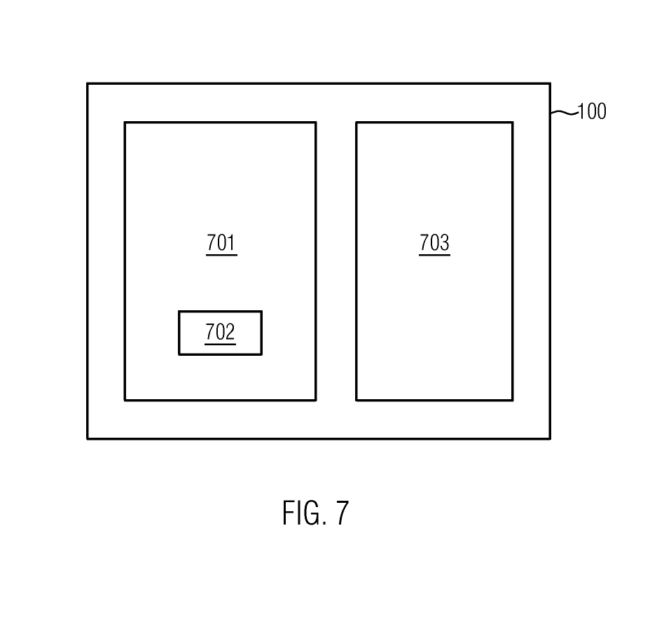

FIG. 7 shows a schematic top view of the semiconductor device 100 described above with reference to FIGS. 1a to 2d, wherein a greater portion of the semiconductor device than the portion shown in FIGS. 1a to 2d is shown.

The semiconductor device 100 can include circuitry 701. The circuitry 701 can include a processor 702. Additionally, the circuitry 701 can include other semiconductor circuits, for example memory circuits. The circuitry 701 can include a plurality of transistors, which can be field effect transistors that are adapted for operation at a relatively low operating voltage. In embodiments, the circuitry 701 can include planar transistors. Alternatively, or additionally, the circuitry 701 can include other types of field effect transistors such as, for example, tri-gate transistors, Fin-FET transistors and/or vertical transistors. Moreover, some or all of the transistors of circuitry 701 can include gate insulation layers including a high-k material having a greater dielectric constant than silicon dioxide and/or gate electrodes including a metal.

The transistors of the circuitry 701 can be adapted for operation at an operating voltage that is substantially lower than the operating voltage of transistor 111, for example at an operating voltage in a range from about 0.5V to about 3.3V.

In addition to circuitry 701, the semiconductor device 100 can include a high voltage circuitry. The high voltage circuitry 703 can include one or more LDMOS transistors, one of the one or more LDMOS transistors being transistor 111 described above with reference to FIGS. 1a to 2d.

The processor 702 can be adapted for applying a gate voltage between the gate electrode 107 and the source region 105 of the transistor 111, and between gate electrodes and source regions of other LDMOS transistors in the high voltage circuitry 703. Thus, the processor 702 can switch the one or more LDMOS transistors in the high voltage circuitry 703 between the ON state and the OFF state.

The processor 702 need not be directly connected to the gate electrodes and source regions of the LDMOS transistors in the high voltage circuitry 703. In embodiments, the circuitry 701 can include an interface circuit (not shown) connected between the processor 702 and the high voltage circuitry 703.

In embodiments, the semiconductor device 100 can be a system-on-a-chip.

The semiconductor devices 300, 400, 500, 600 described above with reference to FIGS. 3 to 6 can have configurations corresponding to that of semiconductor device 100 shown in FIG. 7, wherein the respective transistors 311, 411, 511, 611 can be provided in high voltage circuitry similar to the high voltage circuitry 703. Additionally, each of the semiconductor devices 300, 400, 500, 600 can include circuitry similar to circuitry 701, which can include a processor similar to processor 702.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A semiconductor device, comprising:
a semiconductor substrate comprising a first semiconductor material;
a recess in the first semiconductor material, the recess being filled with a second semiconductor material having a different composition than the first semiconductor material; and
a first transistor comprising a source region provided in the first semiconductor material, a drain region, a gate electrode, and a channel region provided in the first semiconductor material and disposed at least partially below the gate electrode, wherein the channel region is arranged at two or more laterally opposite sides of the drain region and the source region is arranged at two or more laterally opposite sides of the channel region, the drain region comprising a low doped drift region and a highly doped region, a dopant concentration in the low doped drift region being at least one of smaller than a dopant concentration in the highly doped region and approximately zero;
wherein at least the low doped drift region is provided in the second semiconductor material.

2. A semiconductor device according to claim 1, wherein the first semiconductor material comprises silicon and the second semiconductor material comprises at least one of silicon germanium and silicon carbide.

3. A semiconductor device according to claim 2, wherein the first transistor further comprises a gate insulation layer between the gate electrode and the channel region, the gate insulation layer comprising a high-k material having a greater dielectric constant than silicon dioxide, and wherein the gate electrode comprises a metal.

4. A semiconductor device according to claim 2, wherein the first transistor further comprises a first shallow trench isolation below an edge of the gate electrode facing the highly doped region.

5. A semiconductor device according to claim 4, wherein the low doped drift region extends below the highly doped region, the first shallow trench isolation and the gate electrode.

6. A semiconductor device according to claim 5, wherein each of the low doped drift region and the highly doped region is provided in the second semiconductor material, and wherein the first shallow trench isolation is provided in a trench in the second semiconductor material.

7. (canceled)

8. A semiconductor device according to claim 7, wherein an interface between the low doped drift region and the channel region has a sigma shape.

9. A semiconductor device according to claim 7, wherein an interface between the low doped drift region and the channel region has a rounded shape.

10. (canceled)

11. A semiconductor device according to claim 6, further comprising circuitry comprising a processor, the circuitry comprising a plurality of second transistors on the substrate, an operating voltage of the plurality of second transistors being lower than an operating voltage of the first transistor.

12. A semiconductor device according to claim 11, wherein the circuitry applies a gate voltage between the source region and the gate electrode of the first transistor.

13. A semiconductor device according to claim 12, wherein the semiconductor device comprises a system on a chip.

14. A semiconductor device according to claim 13, wherein the channel region extends all around the drain region and the source region extends all around the channel region and the drain region.

15. A semiconductor device according to claim 13, wherein the drain region has an approximately circular shape and wherein each of the gate electrode and the source region has an approximately circular ring shape.

16. A semiconductor device according to claim 14, wherein the drain region has an approximately rectangular shape, and wherein each of the gate electrode and the source electrode has an approximately rectangular annulus shape.

17. A semiconductor device according to claim 13, wherein the gate electrode has a first portion and a second portion arranged at two opposite sides of the drain region, and wherein the source region has a first portion and a second portion, the first portion of the source region being arranged adjacent the first portion of the gate electrode, the second portion of the source region being arranged adjacent the second portion of the gate electrode.

18. A semiconductor device according to claim 13, further comprising at least one substrate contact region near the source region and separated from the source region by a second shallow trench isolation.

19. A method, comprising:
providing a semiconductor substrate comprising a first semiconductor material;
forming a recess in the first semiconductor material;
filling the recess with a second semiconductor material having a different composition than the first semiconductor material; and
forming a first transistor comprising a source region provided in the first semiconductor material, a drain region, a gate electrode, and a channel region provided in the first semiconductor material and disposed at least partially below the gate electrode, wherein the channel region is arranged at two or more laterally opposite sides of the drain region and the source region is arranged at two or more laterally opposite sides of the channel region, the drain region comprising a low doped drift region and a highly doped region, a dopant concentration in the low doped drift region being at least one of smaller than a dopant concentration in the highly doped region and approximately zero;
wherein at least the low doped drift region is formed in the second semiconductor material.

20. A method according to claim 19, wherein forming the recess comprises performing a crystallographically anisotropic etch process, the crystallographically anisotropic etch process providing the recess with sigma-shaped sidewalls.

21. A method according to claim 19, wherein forming the recess comprises performing a substantially isotropic etch process, the substantially isotropic etch process providing the recess with rounded sidewalls.

22. A method according to claim 19, wherein forming the first transistor comprises a gate-first process.

23. A method according to claim 19, wherein forming the first transistor comprises a replacement gate process.
